(19) United States
(12) Patent Application Publication
(10) Pub. No.: US 2023/0311404 A1
(43) Pub. Date: Oct. 5, 2023

(54) IMPRINT APPARATUS

(71) Applicant: Samsung Display Co., LTD., Yongin-si (KR)

(72) Inventors: Kangwon LEE, Suwon-si (KR); Soo Beom JO, Incheon (KR); Dong Kyun KO, Hwaseong-si (KR); Kyungjoo MIN, Yongin-si (KR); Eun Chan LIM, Asan-si (KR); Myung Soo HUH, Suwon-si (KR)

(21) Appl. No.: 17/989,758

(22) Filed: Nov. 18, 2022

(30) Foreign Application Priority Data
Mar. 29, 2022 (KR) 10-2022-0038826

(51) Int. Cl. B29C 59/00; B29C 59/04

(52) U.S. Cl. CPC B29C 59/002; B29C 59/046

(57) ABSTRACT

An imprint device according to an embodiment includes: a stage, which supports a substrate; a press roller, which presses a film with respect to the substrate; a first load cell and a second load cell, which are disposed corresponding to opposite ends of the press roller, respectively; and a controller, which monitors a release state of the film based on an output of the first load cell and an output of the second load cell.

This application claims priority Korean Patent Application No. 10-2022-0038826, filed on Mar. 29, 2022, and all the benefits accruing therefrom under 35 U.S.C. § 119, the content of which in its entirety is herein incorporated by reference.

### BACKGROUND

### (a) Technical Field

This disclosure relates to an imprint device and a method for monitoring a process performed using an imprint device.

### (b) Description of the Related Art

Although imprint technology is a relatively simple mechanical transfer method, it may form patterns with a resolution of nanometer order (e.g., 10 nanometers (nm) or less) like photolithography technology. In the imprint technology, resin material, pressurization method, curing uniformity, and the like are major factors, and they must be implemented simultaneously to obtain a pattern of desired shape and quality.

The imprint method includes a hard imprint method and a soft imprint method. The hard imprint method is a method of transferring a pattern by pressing a hard master having a desired pattern and dimensions to a target substrate coated with a resin. The plate-to-plate based hard imprint method may not be suitable for large areas because it is difficult to secure uniformity of pressure due to flatness error caused by a thickness difference between a master and a substrate. In the soft imprint method, the master pattern is first transferred to a flexible substrate such as a film to produce a stamp, and the pattern is secondary transferred by pressing the stamp to the target substrate coated with a resin. The roll-to-plate-based soft imprint method may be advantageous in obtaining uniformity of pressure even in a large area, and may be advantageous in terms of productivity as continuous substrate conveyance is possible.

### SUMMARY

Imprint technology includes a pressurization process and a release process, and uniformity management of the remaining film during the pressurization process and pattern tearing during the release process may be a problem. The expansion of the imprint region may increase the risk during the pressurization or release process as the application area becomes larger.

Embodiments are to provide an imprint device that can monitor an abnormal state during a release process performed using the imprint device.

An imprint device according to an embodiment includes: a stage, which supports a substrate; a press roller, which presses a film with respect to the substrate; a first load cell and a second load cell, which are disposed corresponding to opposite ends of the press roller, respectively; and a controller, which monitors a release state of the film based on an output of the first load cell and an output of the second load cell.

The controller may monitor the release state based on a sum of the outputs of the first and second load cells.

The controller may monitor the release state by using fluctuation of the sum of the outputs.

The controller may determine whether a defect occurs by comparing the sum of the outputs with a sum of outputs of the first and second load cells for a normal release region of the film.

The sum of the output may be represented as given in Equations (1) to (3):

Σ(F_{L}+F_{R}) (1)

F_{L}=F_L_In+F_L_Re−F_L_De (2)

F_{R}=F_R_In+F_R_Re−F_R_De (3)

where F_{L} may denote the output of the first load cell, F_{R} may denote the output of the second load cell, F_L_In may denote an initial value considering a setup error of the left load cell, F_L_Re may denote a reaction force of the film F applied to the left load cell, F_L_De may denote a release force of the film acting on the left load cell, F_R_In may denote an initial value considering a setup error of the second load cell, F_R_Re may denote a reaction force of the film acting on the second load cell, and F_R_De may denote a release force of the film acting on the second load cell.

The origin positions of the first and second load cells may be set while the press roller is spaced apart from the substrate.

The imprint device may further include a support unit, which supports the film, where the support unit may include a roller, which controls a tension of the film by being connected to an actuator or by own weight of the roller.

The imprint device may further include: a bearing, which rotatably supports the opposite ends of the press roller; and a bridge, which is disposed between the press roller and the first and second load cells and includes a first side portion and a second side portion.

The press roller may be fixed to the bridge through the bearing, and the first load cell and the second load cell may be connected with the first side portion and the second side portion, respectively.

The imprint device may further include a floating joint, which corrects an assemble error by being connected to each of the first load cell and the second load cell.

The imprint device may further include a driving apparatus, which is connected with the floating joint and independently controls vertical movement of opposite ends of the press roller.

The imprint device may further include a frame, which movably supports the bridge, and

The driving apparatus may include a motor and ball screws fixed to the frame.

An imprint device according to an embodiment includes: a pressing unit, which presses a film against a resin-coated substrate or a master; and a controller, which controls operation of the pressing unit. The pressing unit includes a press roller, which presses the film while being in contact with the film, a bridge, which is connected with the press roller, and a first load cell and a second load cell, which are connected with the bridge. The controller monitors a release state of the film based on a sum of an output of the first load cell and an output of the second load cell.

The controller may monitor the release state by using fluctuations in the sum of the outputs.

The controller may determine whether a defect occurs by comparing the sum of the outputs with a sum of outputs of the first and second load cells for a normal release region of the film.

The sum of the outputs may be represented as given in Equations (1) to (3):

Σ(F_{L}+F_{R}) (1)

F_{L}=F_L_In+F_L_Re−F_L_De (2)

F_{R}=F_R_In+F_R_Re−F_R_De (3)

where F_{L} may denote the output of the first load cell, F_{R} may denote the output of the second load cell, F_L_In may denote an initial value considering a setup error of the left load cell, F_L_Re may denote a reaction force of the film F applied to the left load cell, F_L_De may denote a release force of the film acting on the left load cell, F_R_In may denote an initial value considering a setup error of the second load cell, F_R_Re may denote a reaction force of the film acting on the second load cell, and F_R_De may denote a release force of the film acting on the second load cell.

The imprint device may further include comprising a support unit, which supports the film, where the support unit may include a roller, which controls a tension of the film by being connected to an actuator or by own weight of the roller.

The imprint device may further include a bearing, which rotatably supports opposite ends of the press roller. The bridge may be disposed between the press roller and the first and second load cells and may include a first side portion and a second side portion. The press roller may be fixed to the bridge through the bearing, and the first load cell and the second load cell may be connected with the first side portion and the second side portion, respectively.

The imprint device may further include a floating joint, which corrects an assemble error by being connected to each of the first load cell and the second load cell.

The imprint device may further include a driving apparatus, which is connected with the floating joint and independently controls vertical movement of each of the opposite ends of the press roller.

The imprint device may further include a frame, which movably supports the bridge, and the driving apparatus may include a motor and ball screws fixed to the frame.

According to the embodiments, it is possible to monitor an abnormal state during the release process during pattern transfer using an imprint device. For various process defects that may occur in the release process, accidents due to abnormal conditions or deterioration of pattern quality can be checked in real time by checking and monitoring the change in the sum of the output of the load cell, thereby effectively improving yield and productivity through quality management. In addition, according to the embodiments, there is an advantageous effect that can be recognized throughout the specification.

### BRIEF DESCRIPTION OF THE DRAWINGS

FIG. 1 schematically illustrates an imprint device according to an embodiment.

FIG. 2 is a schematic view of an imprinting and etching process according to the embodiment.

FIG. 3 is a front view that schematically illustrates the imprint device according to the embodiment.

FIG. 4 is a side view that schematically illustrates the imprint device shown in FIG. 3.

FIG. 5 and FIG. 6 are drawings showing the pressing process and the releasing process performed using the imprint device shown in FIG. 4.

FIG. 7 is a schematic diagram of a correlation between the release state and the release force.

FIG. 8 is a schematic cross-sectional view of a display panel according to an embodiment.

### DETAILED DESCRIPTION

With reference to the accompanying drawing, the invention will be described in detail such that a person of an ordinary skill can easily perform it in this art.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

In addition, unless explicitly described to the contrary, the word “comprise”, and variations such as “comprises” or “comprising”, will be understood to imply the inclusion of stated elements but not the exclusion of any other elements.

In addition, when “connected to” in the entire specification, this does not only mean that two or more constituent elements are directly connected, but also means that two or more constituent elements are indirectly connected, physically connected, and electrically connected through other constituent elements, or being referred to by different names depending on the position or function, while being integral.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the drawing, the symbol x used to indicate a direction is a first direction, y is a second direction that is perpendicular to the first direction, and z is a third direction that is perpendicular to the first direction and the second direction.

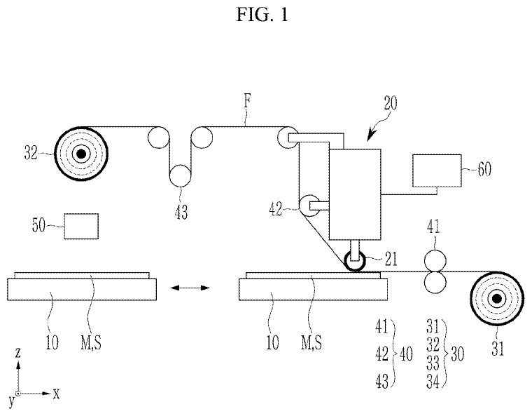

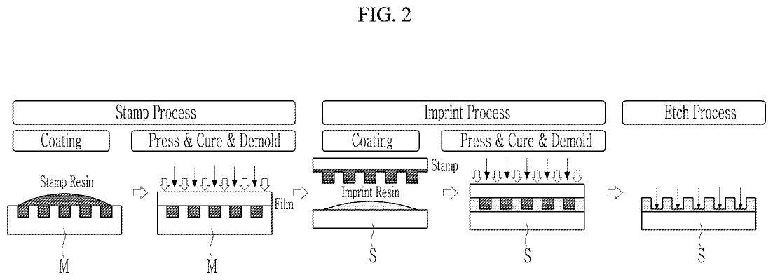

FIG. 1 schematically illustrates an imprint device according to an embodiment, and FIG. 2 is a schematic view of an imprinting and etching process according to the embodiment.

Referring to FIG. 1 and FIG. 2, an imprint device and an imprint method using a roll-to-plate-based transfer method are disclosed. The imprint device may include a stage 10, a pressing unit 20, a roller unit 30, a support unit 40, a coating unit 50, a controller 60, and the like.

The stage 10 may support a master M in which a master pattern is formed in a stamping process. In addition, the stage 10 may support a substrate S to which the pattern is transferred in an imprint process. The stage 10 may be installed between the pressing unit 20 and the coating unit 50 and movably between the pressing unit 20 and the coating unit 50 in a first direction (x). The imprint device may include a rail, a linear motor, and the like for movement of the stage 10.

The pressing unit 20 may press a film F against the master M or substrate S. The pressing unit 20 may include a press roller 21, and the press roller 21 may contact the film F with the master M or the substrate S while moving in the first direction (x). Particularly, when pressed by the press roller 21, the film F may contact the resin coated on the master M or the resin coated on the substrate S rather than contacting the master M or the substrate S itself. When the press roller 21 returns to its original position, the film F may be separated from the master M or the substrate S.

The roller unit 30 may wind or unwind the film F. The roller unit 30 may include a roller 31 for supplying the film F and a roller 32 for collecting the film F, and the rollers 31 and 32 may be positioned on opposite sides of the pressing unit 20 in the first direction (x). By the action of the rollers 31 and 32, the film F may be moved between the stage 10 and the pressing unit 20 while being unwound in the roller 31 and wound on roller 32.

The support unit 40 may include rollers 41, 42, and 43 that support the film F away from the master M or the substrate S and control the tension of the film F. The rollers 41, 42, and 43 may include a roller 41 that guides the movement of the film F from the roller 31 toward the pressing unit 20, the roller 42 that supports the film F for the film F to be away from the master M or the substrate S and guides the movement of the film F toward the roller 32, and the roller 43 that controls the tension of the film F when the film F is pressed by the pressing unit 20 or when the film F is released. The roller 41 may be positioned between the roller 31 and the pressing unit 20 in the first direction (x), and the rollers 42 and 43 may be positioned between the pressing unit 20 and the roller 32.

The roller 41 may separate the tension of the film F on one side and the other side of the roller 41 in the first direction (x). The roller 42 may be installed to support the film F in a higher position than the roller 41. For example, the roller 42 may be mounted on a side of the pressing unit 20 and positioned higher than the press roller 21. Accordingly, the film F may be disposed in an inclined state from the roller 41 to the roller 42 so as to be further spaced apart from the master M or the substrate S which is disposed on the stage 10. The roller 43 may maintain the tension between the roller 41 and the roller 42. When the press roller 21 of the pressing unit 20 moves in the first direction (x) while in contact with the film F, the tension of the film F between the roller 41 and the roller 42 may change. The tension of the film F can be controlled to be constant by the weight of the roller 43 or by other auxiliary means (e.g., a load by an actuator such as a cylinder connected to the roller 43). The support unit 40 may further include additional rollers that match or cooperate with the rollers 41, 42, and 43. For example, as illustrated, the support unit 40 may include another roller mounted on a side of the pressing unit 20 in a higher position than the roller 42.

The coating unit 50 may be coated with a resin on the master M or the substrate S. The coating unit 50 may coat the resin for stamping on the master M and the resin for imprinting on the substrate S in a way such as an inkjet, a slot die, and dispensing. The resin may be a photo-curable resin in which a curing reaction proceeds within a short time when light having high energy in a specific wavelength range such as ultraviolet (“UV”) is irradiated. The photo-curable resin may be a photo-curable acryl-based resin, a photo-curable vinyl ether-based resin, or the like.

The controller 60 may control the operation and overall operation of each constituent element of the imprint device. In addition, the controller 60 may monitor the entire process, such as the stamp process and the imprint process, and may determine whether there is an abnormality.

The imprint device may be used in the stamp process of transferring the pattern formed on the master M to the film F and the imprint process of transferring the pattern transferred to the film F to the substrate S.

When describing each process, the stamping process may be a process of forming a stamping pattern on the film F to produce the film F as a stamp. In the stamping process, the stage 10 may support the master M on which the master pattern is formed. After the resin for stamping is coated on the master M by the coating unit 50, the film F may be pressed toward the master M by the pressing unit 20 (particularly, as the press roller 21 moves toward the roller 42 in a direction opposite to the first direction (x)), and thus the stamping pattern may be formed on the film F. When the stamping pattern is formed, the resin may be cured by irradiating ultraviolet (UV) light while the pressing unit 20 presses the film F toward the master M. Then, a stamp can be manufactured by releasing (peeling) the film F on which the stamping pattern is formed from the master M. The release of the film F from the master M may be performed as the press roller 21 moves toward the roller 41 in the first direction (x). The pressurization and release according to the movement of the press roller 21 in the first direction (x) may occur because the film F is disposed in an inclined state on the stage 10 while maintaining the tension.

The film F may be a polymer film such as polycarbonate, polyethylene terephthalate, polyethylene naphthalene, or polyimide

The film F may be made of or include a material such as thin glass or a metal.

The imprint process may be a process of transferring the stamping pattern formed on the film F to the target substrate S. In the imprint process, the stage 10 may support the substrate S. The substrate S may be a substrate forming an electronic device such as a substrate of a display panel or a wafer. A layer (e.g., a conductive layer, a semiconductor layer, an insulating layer, etc.) to be patterned by etching may be formed on the substrate S. After the resin for imprint is coated on the master M by the coating unit 50, the film F may be pressed toward the substrate S by the pressing unit 20 (particularly, as the press roller 21 moves toward the roller 42 in a direction opposite to the first direction (x)), and thus a pattern that is complementary to the stamping pattern formed on the film F and corresponding to the master pattern formed on the mask M may be formed on the substrate S. When the pattern is formed on the substrate S, the resin may be cured by irradiating ultraviolet (UV) light while the pressing unit 20 presses the film F toward the substrate S. Then, the film F on which the stamping pattern is formed may be released (separated, peeled) from the substrate S. The release of the film F from the substrate S may be performed as the press roller 21 moves toward the roller 41 in the first direction (x).

When the imprint process is completed, the layer under the pattern may be etched using the pattern formed on the substrate S as a mask. After etching is complete, the pattern can be removed.

As above, the imprint device using the roll-to-plate-based (or roll-to-roll-based) pressing method may improve the pressing uniformity and release stability. However, in order to improve yield and productivity through quality control, it may be desirable to monitor abnormal conditions during the releasing process for various causes due to defects occurred in the transfer process. Hereinafter, characteristics of the imprint device that can monitor an abnormal state during the release process will be described in more detail.

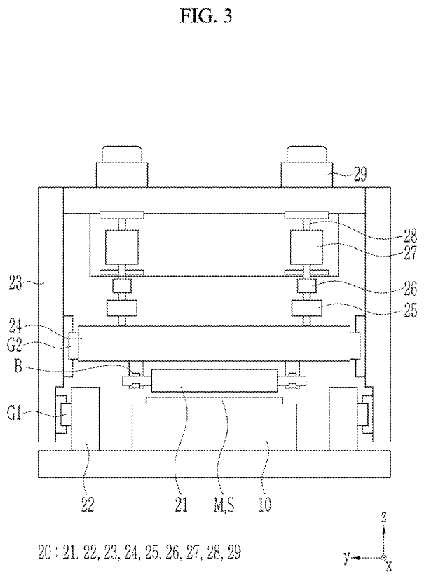

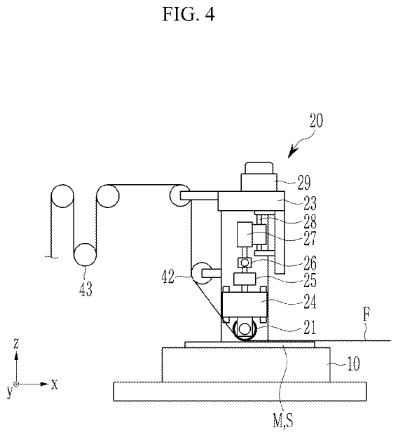

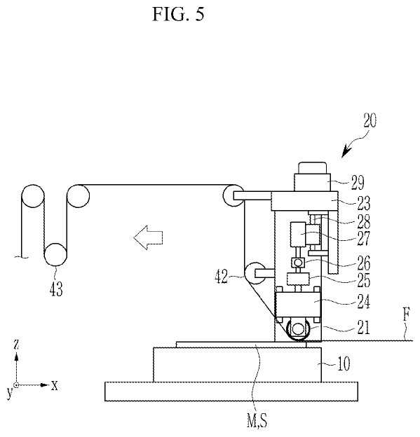

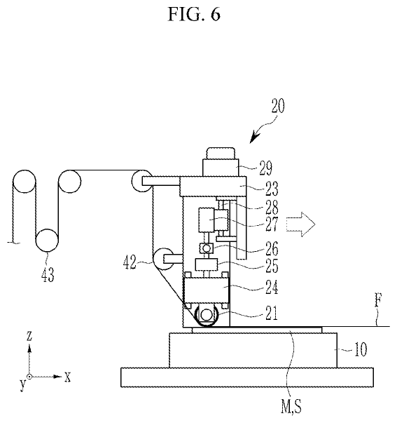

FIG. 3 is a front view that schematically illustrates the imprint device according to the embodiment, and FIG. 4 is a side view that schematically illustrates the imprint device shown in FIG. 3. FIG. 5 and FIG. 6 are drawings showing the pressing process and the releasing process performed using the imprint device shown in FIG. 4.

Referring to FIG. 3 and FIG. 4, the stage 10, the press unit 20, and some rollers 42 and 43 in the above-described imprint device are illustrated. In FIG. 4, a part of the configuration shown in FIG. 3, that is, the base 22, the guide G1, and the frame 23 of FIG. 3 are partially omitted for clearly illustrate a configuration of the pressing unit 20.

The master M or the substrate S may be placed on the stage 10, and the pressing unit 20, particularly, the press roller 21, may be placed on the master M or the substrate S. The pressing unit 20 includes the press roller 21, a base 22, a frame 23, a bridge 24, a load cell 25, a floating joint 26, a table 27, a ball screw 28, a motor 29, and the like.

The press roller 21 may be rotatably disposed around a rotation axis that is parallel to a second direction (y). For example, opposite ends of the press roller 21 are rotatably supported by bearings B, and may be connected to a bridge 24 with the bearings B connected thereto.

The base 22 may be positioned on opposite sides of the stage 10, and may be disposed long along the first direction (x). The frame 23 can hold and move the components of the pressing unit 20. The frame 23 may have a gantry-like structure including vertical portions extending in a third direction (z) and horizontal portions connected with upper ends of the vertical portions and extending in the second direction (y) on opposite sides of the stage 10. The frame 23 may be movably coupled to a guide G1 provided on the base 22 along the first direction (x). The pressing unit 20 may include a driving apparatus (not shown) such as a motor that moves the frame 23.

The bridge 24 may extend along the second direction y. Opposite ends of the bridge 24 may be movably coupled to a guide G2 provided in the frame 23 along the third direction (z). The press roller 21 is coupled to a bridge 24 that can move in the third direction (z), and the bridge 24 is coupled to the frame 23 that may move in the first direction (x) such that the press roller 21 can move in the first direction (x) and the third direction (z) according to the movement of the frame 23 and the bridge 24. For example, in a state illustrated in FIG. 4, the press roller 21 may move up, down, left, and right, and such a movement may be controlled by the controller 60 described with reference to FIG. 1.

The load cell 25 is disposed on the bridge 24 to measure the reaction force inside the imprint device. For control of pressurization pressure and pressurization uniformity of the press roller 21, the controller 60 may control the position of the press roller 21 using an output of load cell 25. A plurality of load cells 25 may be provided, and, for example, referring to FIG. 3, the load cell 25 connected to the left side (or the first side) of the bridge 24 and the load cell 25 connected to the right side (or the second side) of the bridge 24 may be included. Hereinafter, to distinguish between the load cell 25 connected to the left side of the bridge 24 from the load cell 25 connected to the right side of the bridge 24, they will be called the left load cell 25 and the right load cell 25, or the first load cell 25 and the second load cell 25, respectively. The left load cell 25 and the right load cell 25 may be positioned to correspond to opposite ends of the press roller 21.

The load cell 25 may be connected to a table 27 through a floating joint 26 in the third direction (z), the table 27 may be connected to a ball screw 28, and the ball screw 28 may be connected to a motor 29. The floating joints 26, the table 27, the ball screw 28, and the motor 29 each may be provided in plural corresponding to the number of load cells 25. In the illustrated embodiment, the pressing unit 20 includes two each of the load cell 25, the floating joint 26, the table 27, the ball screw 28, and the motor 29.

The ball screw 28 and the motor 29 are driving devices that can move the press roller 21 in the third direction (z), and can be fixed to the frame 23. The ball screw 28 can convert the rotation motion of the motor 29 into a straight-lined motion parallel to the third direction (z). In another embodiment, as a driving apparatus, actuators such as cylinders and pistons may be used instead of the combination of the ball screw 28 and the motor 29. The floating joint 26 may be inserted to correct an assembly error between the driving apparatus and the press roller 21 or to solve a shaft misalignment problem, and minimize the effect of the mechanical assembly error. The floating joint 26 may be positioned between the table 27 and the load cell 25 and can be connected to the table 27 and the load cell 25. The table 27 may mechanically connect the ball screw 28 and the floating joint 26. When the ball screw 28 moves up and down by the operation of the motor 29, the table 27, the floating joint 26, the load cell 25, and the bridge 24 connected directly or indirectly to the ball screw 28 can move up and down together, and the press roller 21 connected to the bridge 24 can also move up and down. Since the load cell 25, the floating joint 26, the table 27, the ball screw 28, and the motor 29 are connected to the left and right parts of the bridge 24, respectively, the left and right parts of the bridge 24 and the corresponding left and right parts of the press roller 21 can be independently controlled.

Regarding the imprint process, FIG. 5 illustrates the operation of the pressing unit 20 during the pressing process as an example, and FIG. 6 illustrates the operation of the pressing unit 20 during the release process as an example. After mounting the substrate S on the stage 10 and coating the resin on the substrate S, the stage 10 may be disposed in alignment with the pressing unit 20. Alternatively, the resin-coated substrate S may be mounted on the stage 10 aligned with the pressing unit 20. A film F on which the stamping pattern is formed may be disposed between the substrate S and the press roller 21 in the third direction (z). When the pressing unit 20 contacts the film by adjusting the position of the press roller 21 in the third direction (z) and the press roller 21 is moved in a direction shown in FIG. 5 (i.e., from right to left), the press roller 21 can sequentially press the film F against the resin while making continuous linear contact with the film F. Accordingly, a pattern complementary to the pattern formed on the substrate S can be formed on the resin. Then, the resin may be cured by irradiating ultraviolet (UV) to the resin using an ultraviolet (UV) lamp (not shown).

After the pressing process is completed, the press roller 21 may be positioned at a distance of several tens to several millimeters far from a starting position at which the press roller 21 is in contact with the film F. After that, when the press roller 21 is moved in a direction opposite to the direction progressed in the pressurization process, that is, in the direction shown in FIG. 6 (i.e., from left to right), the film F may be peeled from the substrate S by the tension of the film F while the pressure of the press roller 21 is released. The tension of the film F may be controlled by the roller 43 of the support unit 40. After the film F is peeled off, a pattern complementary to the stamping pattern formed on the film F on the substrate S may be formed by the cured resin.

As described above, the press roller 21 in contact with the film F has opposite ends supported by the bearing B and connected to the bridge 24 guided in the third direction (z), and thus the left part and the right part of the press roller 21 can move in the third direction (z). The origin position of the press roller 21 in the third direction (z) can be detected by change in the output value of the load cell 25 related to a contact with the substrate S. The origin (zero point) of the load cell 25 can be set as a position of the load cell 25 when the press roller 21 is spaced apart from the substrate S (the master M in the stamp process) and the gravity of the structure under the load cell 25 is applied. In the pressing process for pattern formation, the press roller 21 may press the upper surface of the film F by controlling the load in a way that follows a predetermined pressure load. In the release process, the press roller 21 is fixed at a position spaced apart from the film F with respect to the origin position of the press roller 21 in the third direction (z), and the process can proceed. After pattern formation, as the press roller 21 moves in the reverse direction (e.g., upward direction), film F can be physically separated from the substrate S by the tension of the film F, and in this case, the reaction force of the film F is applied to the press roller 21 and an abnormal state during the releasing process can be monitored through the load cell 25. In other words, the controller 60 can monitor the stability of the reaction force by checking the change in the output value of the load cell 25 due to the reaction force against the press roller 21 formed by the film F during the release process.

Due to assembly errors such as the uniformity of the film F during the process, processing errors of the conveying rolls themselves, or parallelism between rolls, the left and right tensions in the width direction (e.g., the second direction (y)) of the film F may change. It may be difficult to detect fluctuations in anomaly of the deformed state only with the output of the load cell 25 for specific positions on the left and right sides of film F. However, although there is such an error, the sum of the tension on the left side and the tension on the right side of film F may be maintained constant. Therefore, by considering the sum of the tension on the left side and the tension on the right side of the film F, the effect of measurement or setting can be offset. Specifically, the controller 60 may monitor whether there is an abnormality during the releasing process by using a change in the sum of the output of the left load cell 25 and the output of the right load cell 25 corresponding to the left and right sides of the film F, respectively.

The sum of an output F_{L} of the left load cell 25 and an output F_{R} of the right load cell 25 may be expressed by Equation (1) below, and the output F_{L} of the left load cell 25 and the output F_{R} of the right load cell 25 may be expressed by Equation (2) and Equation (3) below, respectively.

Σ(F_{L}+F_{R}) (1)

F_{L}=F_L_In+F_L_Re−F_L_De (2)

F_{R}=F_R_In+F_R_Re−F_R_De (3)

In Equation (2), F_L_In denotes an initial value considering a setup error of the left load cell 25, F_L_Re denotes a reaction force of the film F applied to the left load cell 25, and F_L_De denotes the release force of the film F acting on the left load cell 25. In Equation (3), F_R_In denotes an initial value considering an initial setup error of the right load cell 25, F_R_Re denotes a reaction force of the film F acting on the right load cell 25, and F_R_De denotes a release force of the film F acting on the right load cell 25. F_L_Re−F_L_De may correspond to a pressure applied to the press roller 21 by the left side of the film F in contact with the press roller 21 in the third direction (z), and F_R_Re−F_R_De may correspond to a pressure applied to the press roller 21 in the third direction (z) by the right side of the film F in contact with the press roller 21.

Monitoring whether there is an abnormality during the releasing process using the sum of the output F_{L} of the left load cell 25 and the output F_{R} of the right load cell 25 may be applied in the same way in the imprint process as well as in the stamp process.

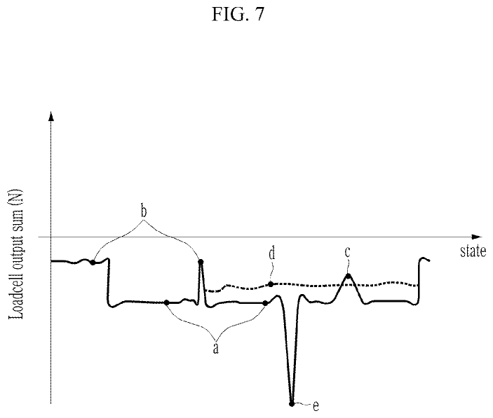

FIG. 7 is a schematic diagram of a correlation between the release state and the release force.

Referring to FIG. 7, types of defects that may occur in the release process and the change in the sum of the output of the load cell 25 depending on the types are illustrated as examples. In the graph, the area a may represent a normal release region (i.e., each area of the dot points indicated by “a”). Areas b, d, and c are regions in which the sum of output is increased compared to the normal release region a, and the area e is a region in which the sum of output is decreased compared to the normal release region a. For example, the area b may be a region where imprint resin is not applied on the substrate S. The area c may be a region where a layer to be patterned on the substrate S is torn off. The area d may be a region in which the stamping pattern is torn off from the film F or a region from which imprint resin is torn off from the substrate S. The area e may be a region in which the substrate S and the film F are bonded.

During the release of the film F, in the area a, the normal release force due to friction between the stamping pattern and the resin pattern may be maintained substantially constant. However, if the resin is not applied, the force that prevents the separation of the stamping pattern from the substrate S during release of film F hardly acts, so the release force can be significantly reduced, and as a result, the sum of the output of the load cell 25 according to Equations (1) to (3) may be reduced.

The layer, the stamping pattern, or the resin may be torn off at a load less than the normal release force generated when the interlocking stamping pattern and the resin pattern are separated during the release process. Then, as a value corresponding to the release force is reduced in Equations (1) to (3), the sum of the output of the load cell 25 may increase.

When the stamping resin is not applied to the film F in the stamping process or there is a region where the stamping pattern is torn during the release process, the corresponding region of the film F is bonded to the imprinting resin in the imprinting process, and thus it may be difficult to separate the corresponding region of the film F from the imprinting resin. Since such a region increases the release force, the sum of outputs of the load cell 25 may decrease according to Equations (1) to (3), described above.

The controller 60 may determine whether it is defective by comparing the output sum of the load cell 25 with the output sum (normal output sum) for the normal release region. Since the release force may be different depending on the pattern even in the normal release region, the normal output sum is not fixed to a specific value, but may be set in a predetermined range. When the output sum is greater or less than a predetermined normal output value, it may be determined that a defect has occurred during the release process. In addition, the type of defect may be predicted or determined according to how far the output sum deviates from the predetermined normal output sum. As such, according to the embodiment, the sum of the outputs of the load cells 25 can be monitored in real time, and whether the pattern transferred to the substrate S is defective can be checked in real time from the anomaly state that can be confirmed from the fluctuation of the sum of the outputs. In addition, it is possible to predict or determine the type of defect that may occur in the process step using the imprint device.

Hereinafter, as an example of an electronic device that can be manufactured using the aforementioned imprint device, a display panel used to display an image on the display device will be described. In a display panel to be described later, a semiconductor layer, a conductive layer, or the like may be formed by etching using a pattern formed by imprint as a mask.

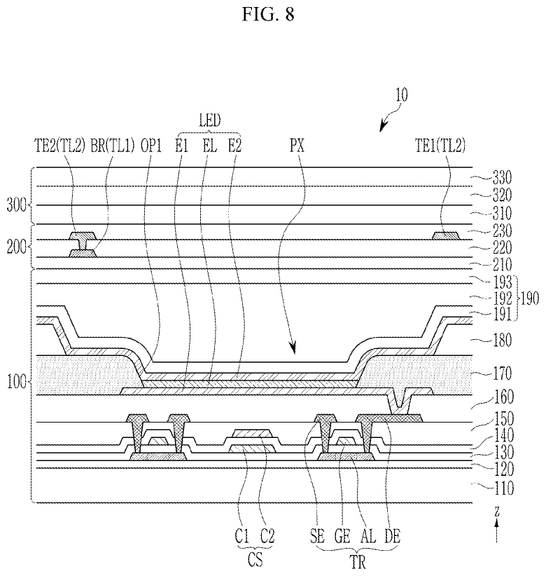

FIG. 8 is a schematic cross-sectional view of a display panel according to an embodiment.

Referring to FIG. 8, a display panel may include a display portion 100, a touch portion 200, and an anti-reflective portion 300.

The display portion 100 may basically include a substrate 110, a transistor TR formed on the substrate 110, and a light emitting diode LED connected to the transistor TR. The light emitting diode LED may correspond to a pixel PX.

The substrate 110 may be a flexible substrate including a polymer such as polyimide, polyamide, or polyethylene terephthalate. The substrate 110 may be a rigid substrate including glass.

A buffer layer 120 may be positioned on the substrate 110. When the semiconductor layer AL is formed, the buffer layer 120 blocks impurities from the substrate 110 to improve the characteristics of the semiconductor layer AL, and may relieve the stress of the semiconductor layer AL by flattening the surface of the substrate 110. The buffer layer 120 may include an inorganic insulating material such as a silicon nitride (SiNₓ), a silicon oxide (SiOₓ), a silicon oxynitride (SiOₓN_{y}), and the like. The buffer layer 120 may include amorphous silicon.

The semiconductor layer AL may be positioned on the buffer layer 120. The semiconductor layer AL may include a first region, a second region, and a channel region between these regions. The semiconductor layer AL may include polysilicon, amorphous silicon, or an oxide semiconductor.

A first gate insulation layer 130 may be positioned on the semiconductor layer AL. The first gate insulation layer 130 may include an inorganic insulating material such as a silicon oxide, a silicon nitride, or a silicon oxynitride, and may be a single layer or multiple layers.

A first gate conductive layer that may include a gate electrode GE may be positioned on the first gate insulation layer 130. The first gate conductive layer may include molybdenum (Mo), aluminum (Al), copper (Cu), titanium (Ti), tungsten (W), or the like, and may be a single layer or multiple layers.

A second gate insulation layer 140 may be positioned on the first gate conductive layer. The second gate insulation layer 140 may include an inorganic insulating material such as a silicon oxide, a silicon nitride, or a silicon oxynitride, and may be a single layer or multiple layers.

A second gate conductive layer that can include a second electrode C2 of the storage capacitor CS may be positioned on the second gate insulation layer 140. The second electrode C2 may overlap the first electrode C1 in the third direction (z), and the first electrode C1, the second electrode C2, and a second gate insulation layer 140 therebetween may form the storage capacitor CS. The second gate conductive layer may include molybdenum (Mo), aluminum (Al), copper (Cu), titanium (Ti), tungsten (W), or the like, and may be a single layer or multiple layers.

An interlayer insulation layer 150 may be positioned on the second gate conductive layer. The interlayer insulation layer 150 may include an inorganic insulating material such as a silicon nitride, a silicon oxide, or a silicon oxynitride, and may be a single layer or multiple layers. When the interlayer insulation layer 150 is a multilayer, the lower layer may include a silicon nitride and the upper layer may include a silicon oxide.

A first data conductive layer that may include a first electrode SE and a second electrode DE of the transistor TR may be positioned on the interlayer insulation layer 150. One of the first electrode SE and the second electrode DE may be a source electrode of the transistor TR, and the other may be a drain electrode of the transistor TR. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like, and may be a single layer or a multilayer. For example, the first data conductive layer may have a triple-layer structure such as titanium (Ti)/aluminum (Al)/titanium (Ti), or a double-layer structure such as titanium (Ti)/copper (Cu).

A planarization layer 160 may be positioned on the first data conductive layer. The planarization layer 160 may include an organic insulating material such as a general-purpose polymer (e.g., polymethyl methacrylate, and polystyrene), a derivative of a polymer having a phenolic group, an acryl-based polymer, an imide-based polymer (e.g., polyimide), a siloxane-based polymer, or the like.

A pixel electrode E1 of the light emitting diode LED may be positioned on the planarization layer 160. The pixel electrode E1 may be connected to the second electrode DE through a contact hole formed in the planarization layer 160. The pixel electrode E1 may be formed of a reflective or semi-transparent conducting material, or may be formed of a transparent conductive material. The pixel electrode E1 may include a transparent conductive material such as an indium tin oxide (“ITO”) or an indium zinc oxide (“IZO”). The pixel electrode E1 may include a metal such as lithium (Li), calcium (Ca), aluminum (Al), silver (Ag), magnesium (Mg), or gold (Au). The pixel electrode E1 may have a multi-layer structure, for example, a triple-layer structure such as ITO/silver (Ag)/ITO.

A partition 170 defining an opening OP1 overlapping the pixel electrode E1 may be positioned on the planarization layer 160, and is also referred to as a pixel defining layer or a bank. The partition 170 may define a light emitting region. The partition 170 may include an organic insulating material such as an acryl-based polymer, an imide-based polymer (e.g., polyimide), or an amide-based polymer (e.g., polyamide). The partition 170 may be a black partition including colored pigments such as black pigments and blue pigments. For example, the partition 170 may include a polyimide binder and a pigment mixed with red, green, and blue. For example, the partition 170 may include a mixture of a cardo binder resin and a lactam black pigment and blue pigment. The partition 170 may contain carbon black. The black partition may improve the contrast ratio and prevent reflection by the underlying metal layer.

An emission layer EL may be positioned on the pixel electrode E1. At least a portion of the emission layer EL may be positioned within an opening OP1. The emission layer EL may include a material layer that uniquely emits light of primary colors such as red, green, and blue. The emission layer EL may have a structure in which material layers emitting light of different colors are stacked. In addition to the emission layer EL, at least one of a hole injection layer (“HIL”), a hole transport layer (“HTL”), an electron transport layer (“ETL”), and an electron injection layer (“EIL”) may be positioned on the pixel electrode E1.

A spacer 180 may be positioned on the partition 170. The spacer 180 may include an organic insulating material such as an acryl-based polymer, an imide-based polymer, or an amide-based polymer.

A common electrode E2 (also called an opposed electrode) may be positioned on the emission layer EL and the partition 170. The common electrode E2 may be positioned over a plurality of pixels PX. The common electrode E2 may include a metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), or the like. The common electrode E2 may include a transparent conductive oxide (“TCO”) such as an indium tin oxide (ITO) or an indium zinc oxide (IZO).

The pixel electrode E1, the emission layer EL, and the common electrode E2 may form a light emitting diode LED, which may be an organic light emitting diode. The pixel electrode E1 may be an anode serving as a hole injection electrode and the common electrode E2 may be a cathode serving as an electron injection electrode, and vice versa. The opening OP1 of the partition 170 may correspond to the light emitting region of the light emitting diode LED.

An encapsulation layer 190 may be positioned on the common electrode E2. The encapsulation layer 190 may seal the light emitting diodes LED and prevent penetration of moisture or oxygen from the outside. The encapsulation layer 190 may be a thin film encapsulation layer including at least one inorganic layer and at least one organic layer stacked on the common electrode E2. For example, the encapsulation layer 190 may have a triple layer structure of a first inorganic layer 191, an organic layer 192, and a second inorganic layer 193.

The first insulation layer 210 of the touch portion 200 may be positioned on the encapsulation layer 190. The first insulation layer 210 may cover the encapsulation layer 190 to protect the encapsulation layer 190 and prevent moisture permeation. The first insulation layer 210 may reduce parasitic capacitance between the common electrode E2 and touch electrodes TE1 and TE2.

A first touch conductive layer TL1 that may include a second bridge BR2 may be positioned on the first insulation layer 210. A second insulation layer 220 may be positioned on the first touch conductive layer TL1. A second touch conductive layer TL2 including the touch electrodes TE1 and TE2 may be positioned on the second insulation layer 220. A passivation layer 230 may be positioned on the second touch conductive layer TL2. The touch electrodes TE1 and TE2 may include first touch electrodes TE1 and second touch electrodes TE2 that form mutual sensing capacitors. The second bridge BR2 may electrically connect the second touch electrodes TE2. For example, adjacent and separated second touch electrodes TE2 may be connected to the second bridge BR2 through contact holes formed in the second insulation layer 220, and may be electrically connected through the second bridge BR2.

The first insulation layer 210 and the second insulation layer 220 may include an inorganic insulating material such as a silicon nitride, a silicon oxide, or a silicon oxynitride, and may be a single layer or multiple layers. The passivation layer 230 may include an organic insulating material such as an acryl-based polymer or an imide-based polymer, or an inorganic insulating material such as a silicon nitride, a silicon oxide, or a silicon oxynitride.

The first touch conductive layer TL1 and the second touch conductive layer TL2 may define an opening overlapping the light emitting region of the light emitting diode LED. The first touch conductive layer TL1 and the second touch conductive layer TL2 are formed of metals such as aluminum (Al), copper (Cu), titanium (Ti), molybdenum (Mo), silver (Ag), chromium (Cr), and nickel (Ni), and may be a single layer or a multilayer. For example, the first touch conductive layer TL1 and/or the second touch conductive layer TL2 may have a triple layer structure such as titanium (Ti)/aluminum (Al)/titanium (Ti).

The anti-reflective portion 300 may be positioned on the passivation layer 230. The anti-reflective portion 300 may include a first phase delay layer 310, a second phase delay layer 320, and a polarization layer 330 sequentially positioned on the passivation layer 230. The anti-reflective portion 300 may be implemented by a combination of a color filter and a light blocking member, a combination of reflective layers causing destructive interference, or the like.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. An imprint device comprising:
a stage, which supports a substrate;
a press roller, which presses a film with respect to the substrate;
a first load cell and a second load cell, which are disposed corresponding to opposite ends of the press roller, respectively; and
a controller, which monitors a release state of the film based on an output of the first load cell and an output of the second load cell.

2. The imprint device of claim 1, wherein
the controller monitors the release state based on a sum of the outputs of the first and second load cells.

3. The imprint device of claim 2, wherein
the controller monitors the release state by using fluctuation of the sum of the outputs.

4. The imprint device of claim 2, wherein
the controller determines whether a defect occurs by comparing the sum of the outputs with a sum of outputs of the first and second load cells for a normal release region of the film.

5. The imprint device of claim 2, wherein
the sum of the outputs is represented as given in Equation (1) to Equation (3):
Σ(F_{L}+F_{R}) (1)
F_{L}=F_L_In+F_L_Re−F_L_De (2)
F_{R}=F_R_In+F_R_Re−F_R_De (3)
where F_{L} denotes the output of the first load cell, F_{R} denotes the output of the second load cell, F_L_In denotes an initial value considering a setup error of the left load cell, F_L_Re denotes a reaction force of the film F applied to the left load cell, F_L_De denotes a release force of the film acting on the left load cell, F_R_In denotes an initial value considering a setup error of the second load cell, F_R_Re denotes a reaction force of the film acting on the second load cell, and F_R_De denotes a release force of the film acting on the second load cell.

6. The imprint device of claim 4, wherein
the origin positions of the first and second load cells are set while the press roller is spaced apart from the substrate.

7. The imprint device of claim 1, further comprising a support unit, which supports the film,
wherein the support unit includes a roller, which controls a tension of the film by being connected to an actuator or by own weight of the roller.

8. The imprint device of claim 1, further comprising:
a bearing, which rotatably supports the opposite ends of the press roller; and
a bridge, which is disposed between the press roller and the first and second load cells and includes a first side portion and a second side portion,
wherein the press roller is fixed to the bridge through the bearing, and
the first load cell and the second load cell are connected with the first side portion and the second side portion, respectively.

9. The imprint device of claim 8, further comprising a floating joint, which corrects an assemble error by being connected to each of the first load cell and the second load cell.

10. The imprint device of claim 9, further comprising a driving apparatus, which is connected with the floating joint and independently controls vertical movement of each of the opposite ends of the press roller.

11. The imprint device of claim 10, further comprising a frame, which movably supports the bridge,
wherein the driving apparatus includes a motor and ball screws fixed to the frame.

12. An imprint device comprising:
a pressing unit, which presses a film against a resin-coated substrate or a master; and
a controller, which controls operation of the pressing unit,
wherein the pressing unit comprises
a press roller, which presses the film while being in contact with the film,
a bridge, which is connected with the press roller, and
a first load cell and a second load cell, which are connected with the bridge, and
wherein the controller monitors a release state of the film based on a sum of an output of the first load cell and an output of the second load cell.

13. The imprint device of claim 12, wherein
the controller monitors the release state by using fluctuations in the sum of the outputs.

14. The imprint device of claim 12, wherein
the controller determines whether a defect occurs by comparing the sum of the outputs with a sum of outputs of the first and second load cells for a normal release region of the film.

15. The imprint device of claim 12, wherein
the sum of the outputs is represented as given in Equations (1) to (3):
Σ(F_{L}+F_{R}) (1)
F_{L}=F_L_In+F_L_Re−F_L_De (2)
F_{R}=F_R_In+F_R_Re−F_R_De (3)
where F_{L} denotes the output of the first load cell, F_{R} denotes the output of the second load cell, F_L_In denotes an initial value considering a setup error of the left load cell, F_L_Re denotes a reaction force of the film F applied to the left load cell, F_L_De denotes a release force of the film acting on the left load cell, F_R_In denotes an initial value considering a setup error of the second load cell, F_R_Re denotes a reaction force of the film acting on the second load cell, and F_R_De denotes a release force of the film acting on the second load cell.

16. The imprint device of claim 12, further comprising a support unit, which supports the film,
wherein the support unit includes a roller, which controls a tension of the film by being connected to an actuator or by own weight of the roller.

17. The imprint device of claim 12, further comprising a bearing, which rotatably supports opposite ends of the press roller,
wherein the bridge is disposed between the press roller and the first and second load cells and comprises a first side portion and a second side portion,
the press roller is fixed to the bridge through the bearing, and
the first load cell and the second load cell are connected with the first side portion and the second side portion, respectively.

18. The imprint device of claim 17, further comprising a floating joint, which corrects an assemble error by being connected to each of the first load cell and the second load cell.

19. The imprint device of claim 18, further comprising a driving apparatus, which is connected with the floating joint and independently controls vertical movement of each of the opposite ends of the press roller.

20. The imprint device of claim 19, further comprising a frame, which movably supports the bridge,
wherein the driving apparatus includes a motor and ball screws fixed to the frame.
